(19) United States
(12) Patent Application Publication
(10) Pub. No.: US 2026/0150370 A1
(43) Pub. Date: May 28, 2026

(54) BACKSIDE CONTACT FOR STACKED FET

(71) Applicant: INTERNATIONAL BUSINESS MACHINES CORPORATION, ARMONK, NY (US)

(72) Inventors: Min Gyu Sung, Latham, NY (US); Ruilong Xie, Niskayuna, NY (US); Tao Li, Slingerlands, NY (US); Julien Frougier, Albany, NY (US); Kisik Choi, Watervliet, NY (US)

(21) Appl. No.: 18/960,440

(22) Filed: Nov. 26, 2024

(51) Int. Cl. H10D 64/23; H10D 64/01; H10D 84/01; H10D 84/83

(52) U.S. Cl. CPC H10D 64/254; H10D 64/01; H10D 64/258; H10D 84/0153; H10D 84/832

(57) ABSTRACT

A microelectronic structure including a first stacked FET and a second stacked FET. The first stacked FET is located adjacent to the second stacked FET. The first stacked FET includes an upper source/drain and a lower source/drain and the first stacked FET includes an upper and lower transistor. An upper connecting via that extends from a frontside region towards a backside region to a middle region. The upper connecting via is located between the first stacked FET and the second stacked FET and the middle region is the region between the upper and lower transistor. A frontside contact connected to a frontside surface of the upper source/drain and a frontside surface of the upper connecting via. A backside connecting via that extends from the backside region to the frontside region, The backside connecting via intersects the upper connecting via at the middle region of the first stacked FET.

### BACKGROUND

The present invention generally relates to the field of microelectronics, and more particularly to forming backside contacts in stack FETs.

Nanosheet is the lead device architecture in continuing CMOS scaling. However, nanosheet technology has shown issues when scaling down such that as the devices becoming smaller and closer together, they are interfering with each other. With the number of devices in a stacked FETs the width requirements are becoming an issue with the scaling down of the stacked FET.

### BRIEF SUMMARY

Additional aspects and/or advantages will be set forth in part in the description which follows and, in part, will be apparent from the description, or may be learned by practice of the invention.

A microelectronic structure including a first stacked FET and a second stacked FET. The first stacked FET is located adjacent to the second stacked FET. The first stacked FET includes an upper source/drain and a lower source/drain and the first stacked FET includes an upper and lower transistor. An upper connecting via that extends from a frontside region towards a backside region to a middle region. The upper connecting via is located between the first stacked FET and the second stacked FET and the middle region is the region between the upper and lower transistor. A frontside contact connected to a frontside surface of the upper source/drain and a frontside surface of the upper connecting via. A backside connecting via that extends from the backside region to the frontside region, The backside connecting via intersects the upper connecting via at the middle region of the first stacked FET.

A microelectronic structure including a first stacked FET and a second stacked FET. The first stacked FET is located adjacent to the second stacked FET. The first stacked FET includes an upper source/drain and a lower source/drain and the first stacked FET includes an upper and lower transistor. An upper connecting via that extends from a frontside region towards a backside region to a middle region. The upper connecting via is located between the first stacked FET and the second stacked FET and the middle region is the region between the upper and lower transistor. A frontside contact connected to a frontside surface of the upper source/drain and a frontside surface of the upper connecting via. A backside connecting via that extends from the backside region to the frontside region, The backside connecting via intersects the upper connecting via at the middle region of the first stacked FET. A shallow trench isolation layer located on the backside surface of the lower source/drain. A connector located inside the shallow trench isolation layer and connected to the backside connecting via.

A method that includes the steps of forming a first stacked FET and a second stacked FET. The first stacked FET is located adjacent to the second stacked FET. The first stacked FET includes an upper source/drain 142 and a lower source/drain 140 and the first stacked FET includes an upper and lower transistor. Forming an upper connecting via 130 that extends from a frontside region towards a backside region to a middle region. The upper connecting via 130 is located between the first stacked FET and the second stacked FET and the middle region is the region between the upper and lower transistor. Forming a frontside contact connected to a frontside surface of the upper source/drain and a frontside surface of the upper connecting via. Forming a backside connecting via that extends from the backside region to the frontside region, The backside connecting via intersects the upper connecting via at the middle region of the first stacked FET.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet stacked FET, in accordance with the embodiment of the present invention.

FIG. 2 illustrates a cross section Y1 of the nanosheet stacked FET after formation of the upper backside contact via, in accordance with the embodiment of the present invention.

FIG. 3 illustrates a cross section Y2 of the nanosheet stacked FET after formation of the upper backside contact via, in accordance with the embodiment of the present invention.

FIG. 4 illustrates a cross section Y1 of the nanosheet stacked FET after additional processing of the stacked nanosheet FETs, in accordance with the embodiment of the present invention.

FIG. 5 illustrates a cross section Y2 of the nanosheet stacked FET after additional processing of the stacked nanosheet FETs, in accordance with the embodiment of the present invention.

FIG. 6 illustrates a cross section Y1 of the nanosheet stacked FET after the stacked nanosheet FETs are flipped over for backside processing and after the formation of the backside interlayer dielectric layer, in accordance with the embodiment of the present invention.

FIG. 7 illustrates a cross section Y2 of the nanosheet stacked FET after the stacked nanosheet FETs are flipped over for backside processing and after the formation of the backside interlayer dielectric layer, in accordance with the embodiment of the present invention.

FIG. 8 illustrates a cross section Y1 of the nanosheet stacked FET after formation of a backside contact via trench, in accordance with the embodiment of the present invention.

FIG. 9 illustrates a cross section Y2 of the nanosheet stacked FET after formation of a backside contact via trench, in accordance with the embodiment of the present invention.

FIG. 10 illustrates a cross section Y1 of the nanosheet stacked FET after formation of the backside contact via, in accordance with the embodiment of the present invention.

FIG. 11 illustrates a cross section Y2 of the nanosheet stacked FET after formation of the backside contact via, in accordance with the embodiment of the present invention.

FIG. 12 illustrates a cross section Y1 of the nanosheet stacked FET after formation of a backside connector trench, in accordance with the embodiment of the present invention.

FIG. 13 illustrates a cross section Y2 of the nanosheet stacked FET after formation of a backside connector trench, in accordance with the embodiment of the present invention.

FIG. 14 illustrates a cross section Y1 of the nanosheet stacked FET after additional processing, in accordance with the embodiment of the present invention.

FIG. 15 illustrates a cross section Y2 of the nanosheet stacked FET after additional processing, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

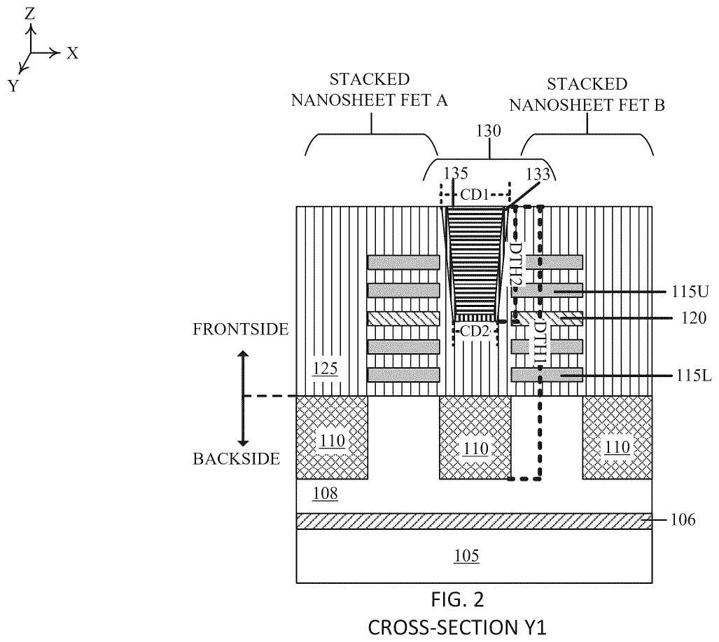

Reference will now be made in detail to the embodiments of the present invention, examples of which are illustrated in the accompanying drawings, where like reference numerals refer to like elements throughout. The present invention is directed towards a contact via that extends from the frontside region to the backside region, more specifically reducing the top critical dimension (e.g., the top frontside width of a contact as it extends in parallel to the gate direction) of the contact via. The contact via is formed in the gate cut region and has a first critical dimension at the top of the contact via and a second critical dimension at the bottom of the contact via, where the first critical dimension is larger than the second critical dimension. The first critical dimension is affected by the desired second critical dimension (i.e., the combined width of the conductive metal and dielectric liner), the depth of the contact via, and the tapered of the contact via (controlled by the etching angle). For example, if the second critical dimension is 30 nanometers (e.g., the combined width of 20 nanometers for conductive metal, plus 10 nanometers of dielectric liner), a taper angle of about 87°, and a depth to the backside region (which is about 180 nanometers, as illustrated in FIG. 2 as dashed line DTH1), would lead to the first critical dimension to be about 50 nanometers. The first critical dimension of the contact via affects the spacing of adjacent elements. The present invention is directed towards reducing the spacing requirements of the first critical dimension, which is achieved by reducing the depth of the contact via and creating a second contact via that extends from the backside region. By reducing the depth of the contact via to around the depth of the upper nanosheet FET, for example, about 90 nanometers, where the second critical dimension (for example, about 30 nanometers) and the taper angle (for example, about 87°) are constant, then the first critical dimension is reduced to, for example, about 40 nanometers. This is about a 10 to 25% reduction of the first critical dimension, which allows for more space to scale down the stacked nanosheet FETs.

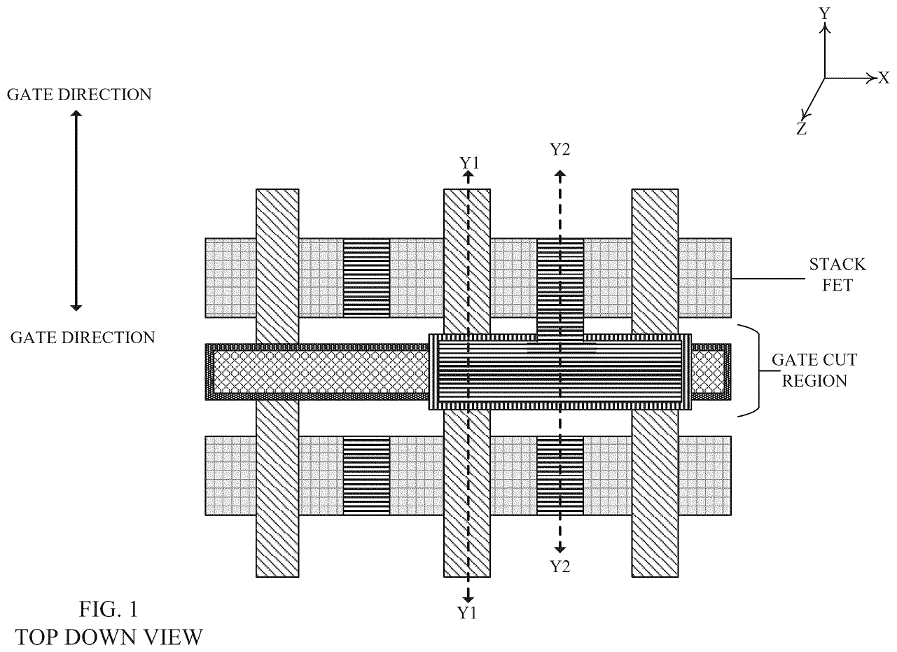

FIG. 1 illustrates a top-down view of a plurality of nanosheet stacked FETs, in accordance with the embodiment of the present invention. Cross-section Y1 extends parallel to the gate direction and extends through the gate region. Cross-section Y2 extends parallel to the gate direction and extends through the source/drain region.

Referring now to FIG. 2, a structure is shown during an intermediate step of a method of fabricating stacked nano devices, such as, a stacked nanosheet transistors structure after formation of the upper backside contact via, according to an embodiment of the invention.

FIG. 2 illustrates the gate region of the nanosheet transistors that includes a first substrate 105, an etch stop 106, a second substrate 108, shallow trench isolation layer 110, a plurality of lower channels 115L, a middle dielectric isolation layer 120, a plurality of upper channel layers 115U, gate 125, the upper backside contact via 130.

The first substrate 105 and the second substrate 108 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of semiconductor materials can be used as the semiconductor material of the first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein.

The stacked nanosheet FET A and stacked nanosheet FET B each include a plurality of lower channel layers 115L, a plurality of upper channel layers 115U, and a middle dielectric isolation layer 120. Gate 125 extends between stacked nanosheet FET A and stacked nanosheet FET B. Gate 125 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. The upper backside contact via 130 is located between the upper sections of the stacked nanosheet FET A and stacked nanosheet FET B, as illustrated in FIG. 2. The upper backside contact via 130 includes an upper dielectric liner 133 and an upper conductive via 135. FIG. 2 illustrates the difference in depths of the full backside contact via (i.e., depth DTH1, which is about 180 nanometers) and the depth of the upper backside contact via 130 (i.e., depth DTH2, which is about 90 nanometers). Depth DTH2 extends from the top surface of gate 125 to around the depth of the middle dielectric isolation layer 120, as illustrated in FIG. 2. The upper backside contact via 130 has a bottom critical dimension, i.e., the second critical dimension CD2, which is comprised of the bottom widths of the upper conductive via 135 and the upper dielectric liner 133. The upper backside contact via 130 has a top critical dimension, i.e., the first critical dimension CD1, which is comprised of the top widths of the upper conductive via 135 and the upper dielectric liner 133. By extending the depth of the upper backside contact via 130 to the second depth DTH2 instead of the first depth DTH1, allows for a reduction of about 10 to 25% of the first critical dimension CD1 of the upper backside contact via 130.

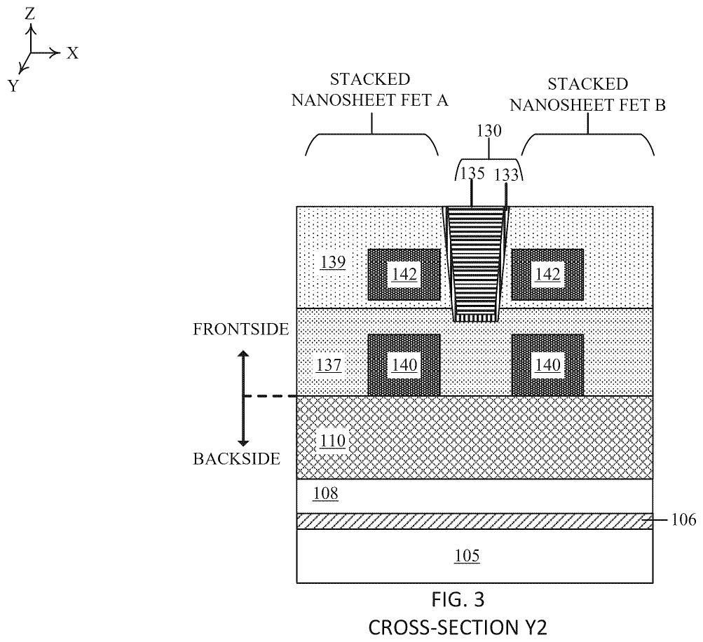

FIG. 3 illustrates the source/drain region that includes lower source/drains 140, a lower interlayer dielectric layer 137, upper source/drains 142, upper interlayer dielectric layer 139, and the upper backside contact via 130. The upper backside contact via 130 extends laterally through the gate region and the source/drain region as illustrated in FIG. 1. The upper backside contact via 130 extends downwards through the upper interlayer dielectric layer 139 into the lower interlayer dielectric layer 137.

The lower source/drains 140 and the upper source/drains 142 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

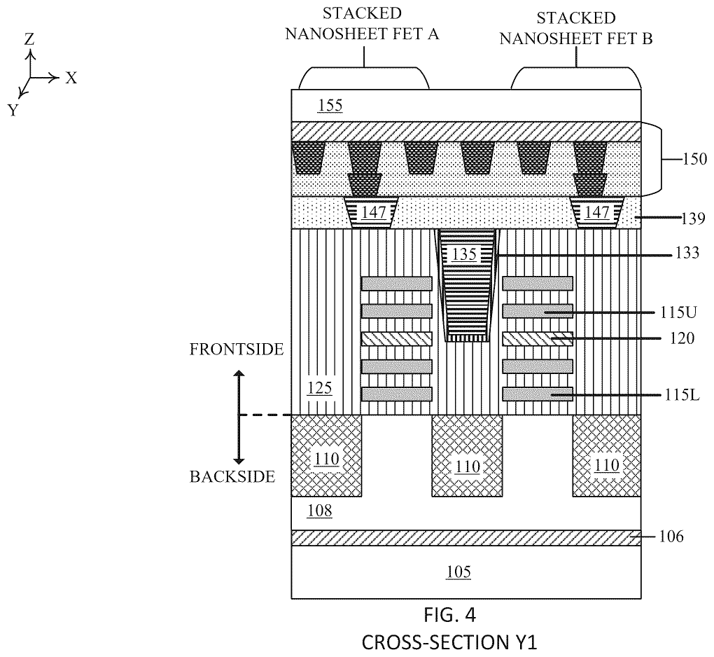

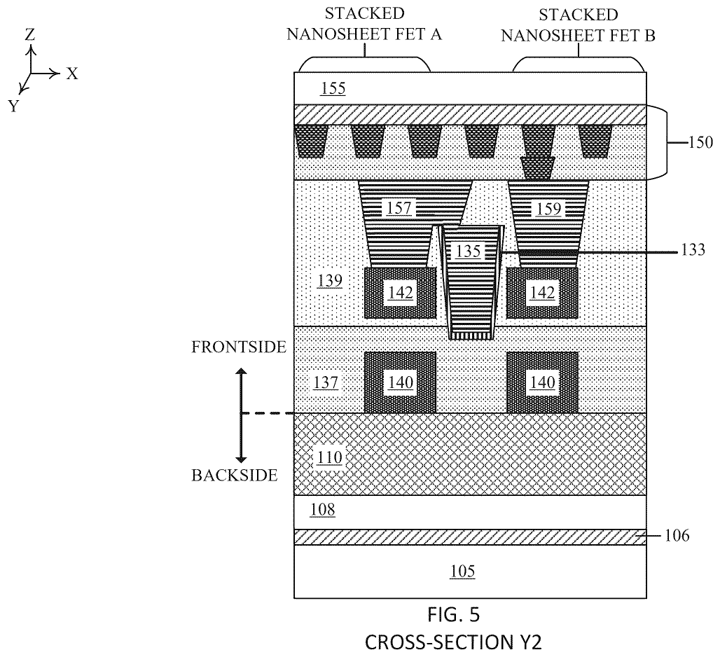

FIGS. 4 and 5 illustrate the processing stage FET after additional processing of the stacked nanosheet FETs. The height of the upper interlayer dielectric layer 139 is increased so that the upper interlayer dielectric layer 139 extends over the top surface of gate 125 and on top of the upper backside contact via 130. A plurality of trenches (not shown) is formed in the upper interlayer dielectric layer 139. These trenches (not shown) are filled with a conductive metal, via a metallization process, to form gate contacts 147, a first source/drain contact 157, and a second source/drain contact 159. The first source/drain contact 157 contacts one of the upper source/drains 142 and is in contact with the upper backside contact via 130. This means that the first source/drain contact 157 is in contact with a top surface of the upper dielectric liner 133 and a top surface of the upper conductive via 135. The second source/drain contact 159 is connected to another upper source/drain 142. An interconnect 150 is formed on top of the upper interlayer dielectric layer 139, on top of the gate contacts 147, and on top of the first and second source/drain contacts 157, 159. The interconnect 150 can include one or more layers, one or more connecting vias, one or more metal lines, or other components. FIGS. 4 and 5 illustrate that the interconnect 150 is connected to gate contacts 147, and the second source/drain contacts 159. Carrier wafer 155 is located on top of the interconnect 150, where the carrier wafer 155 allows for the stacked nanosheet FETs to be flipped over for backside processing.

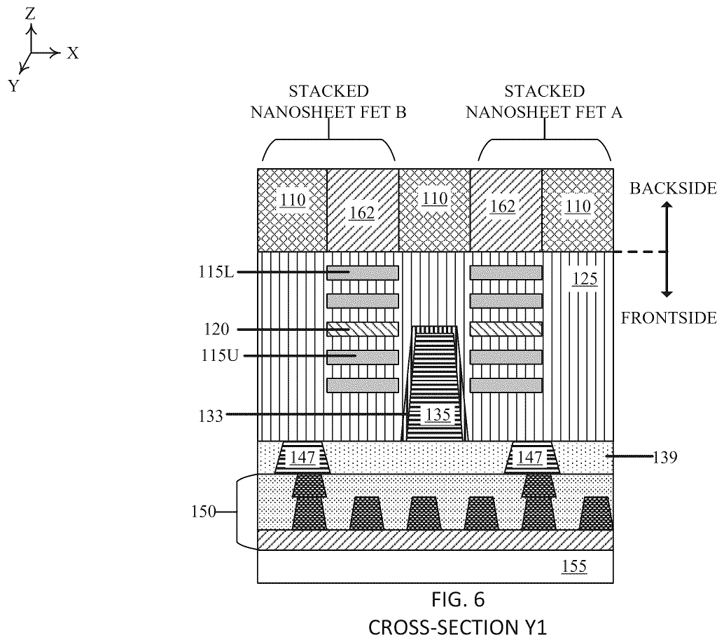

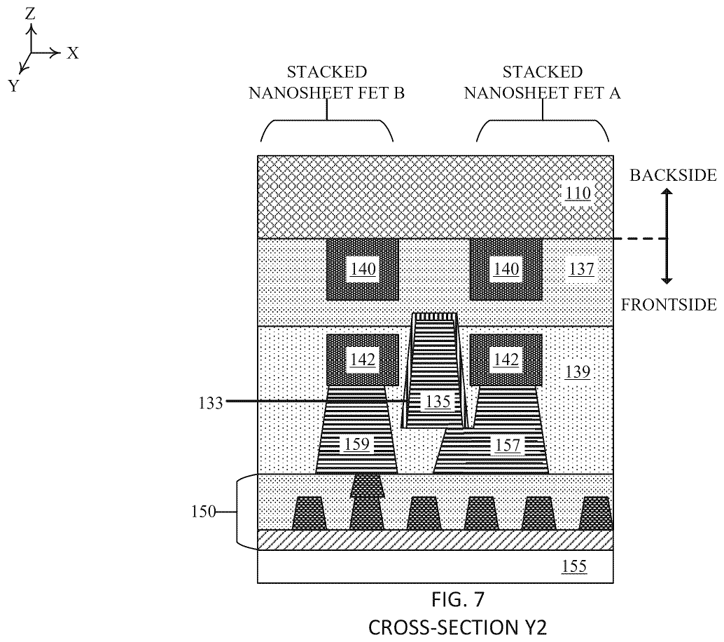

FIGS. 6 and 7 illustrate the processing stage after the stacked nanosheet FETs are flipped over for backside processing and after the formation of the backside interlayer dielectric layer 162. The stacked nanosheet FETs (A and B) are flipped over to allow for the backside of the nanosheet FETs to be processed. The first substrate 105, the etch stop 106, and the second substrate 108 are removed. The removal of the second substrate 108 that was located between sections of the shallow trench isolation layer 110 exposes portions of gate 125. A backside interlayer dielectric layer 162 is formed to fill in the empty sections caused by the removal of the second substrate 108. A planarization process, for example, chemical mechanical planarization (CMP) is utilized to remove excess backside interlayer dielectric layer 162 material and to create a flush/flat surface between the shallow trench isolation layer 110 and the backside interlayer dielectric layer 162. The backside interlayer dielectric layer 162 is vertically aligned with the plurality of lower and upper channel layers 115L, 115U.

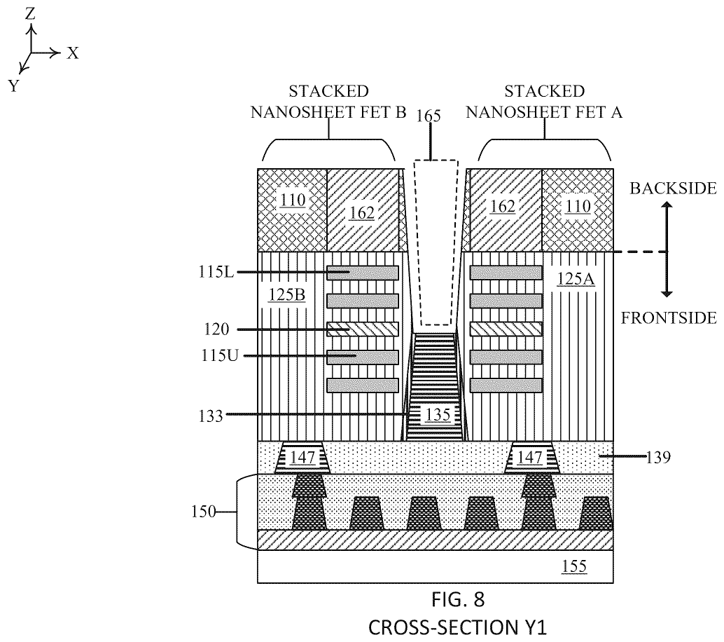

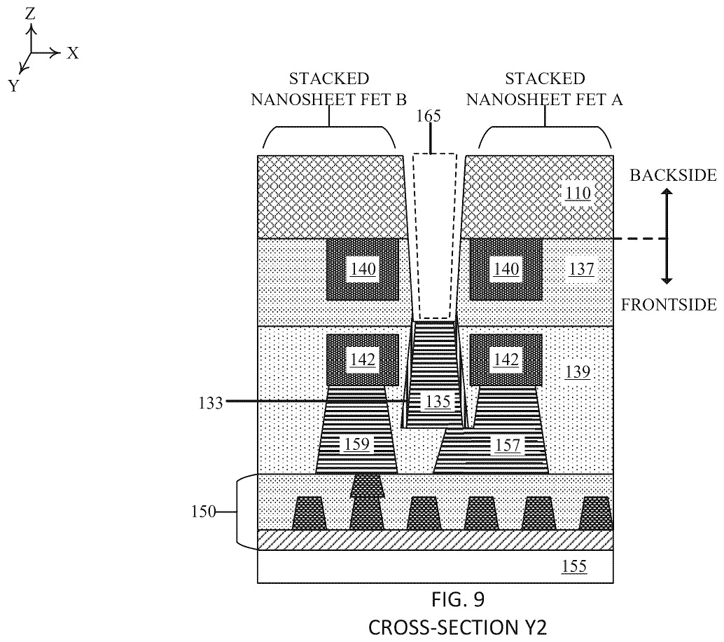

FIGS. 8 and 9 illustrate the processing stage after formation of the backside contact via trench 165. A lithography layer (not shown) is formed on top of the backside interlayer dielectric layer 162 and the shallow trench isolation layer 110. The lithography layer (not shown) is patterned to expose an underlying surface. A backside contact via trench 165 is formed in the shallow trench isolation layer 110 and gate 125, then the lithography layer (not shown) is removed. The backside contact via trench 165 connects to the backside surface of the upper backside contact via 130. Specifically, the backside contact via trench 165 exposes a backside surface of the upper conductive via 135. The upper backside contact via 130 and the backside contact via trench 165 separates gate 125 into gate 125A and gate 125B. The backside contact via trench 165 has tapered sidewalls that angle towards the upper backside contact via 130, meaning that the backside contact via trench 165 width narrows as the backside contact via trench extends towards the upper backside contact via 130.

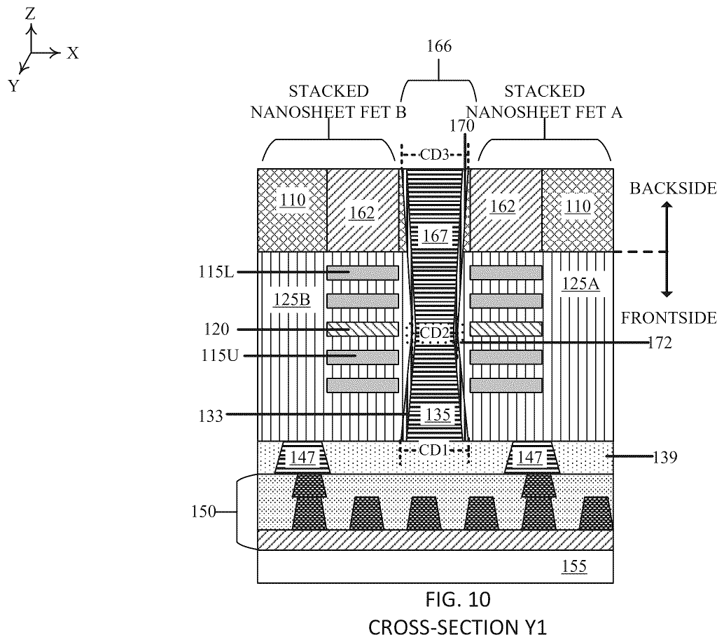

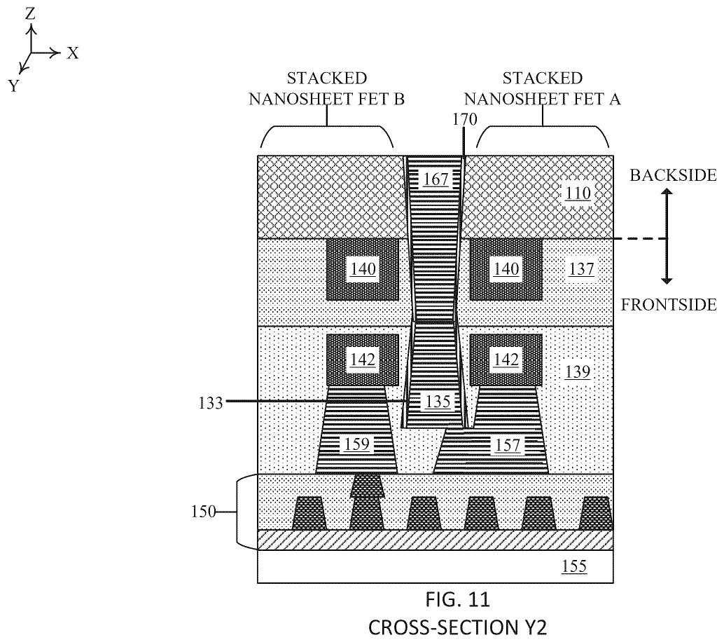

FIGS. 10 and 11 illustrate the processing stage after formation of the backside contact via 166. The backside contact via trench 165 is lined with a backside dielectric liner 170 and a backside conductive via 167. The backside contact via 166 includes the backside dielectric liner 170 and the backside conductive via 167. The backside conductive via 167 contacts the upper conductive via 135. Dashed box 172 emphases the intersection of the upper backside contact via 130 and the backside contact via 166. The upper backside contact via 130 and the backside contact via 166 have tapered side walls that taper towards the intersection point 172. Such that, the intersection point 172 is the narrowest point of both the upper backside contact via 130 and the backside contact via 166. Combined the upper backside contact via 130 and the backside contact via 166 have an hourglass shape profile as viewed in parallel to the gate direction as illustrated in FIGS. 10-15. The width of the intersection point 172 is equal to the second critical distance CD2. The backside contact via 166 has a top width equal to a third critical distance CD3. By forming the backside contact via from the frontside (i.e., the upper backside contact via 130) and the backside (i.e., the backside contact via 166) leads to a reduction of the first critical distance CD1.

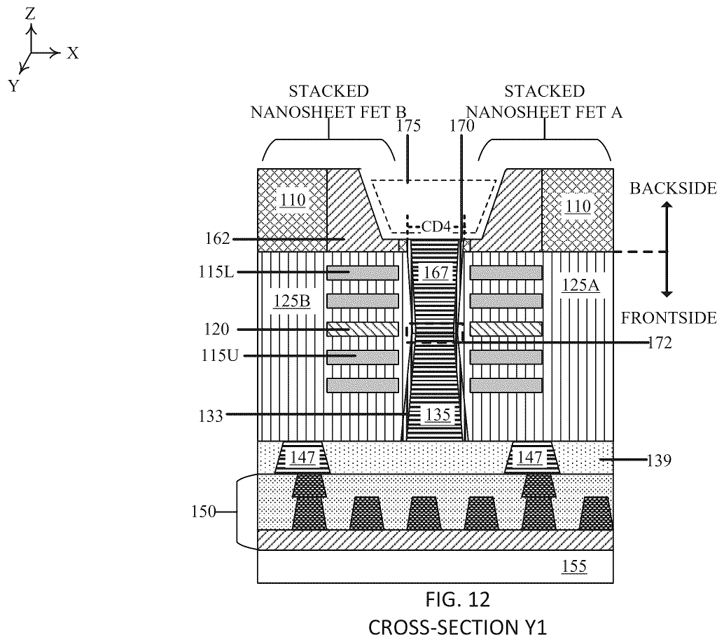

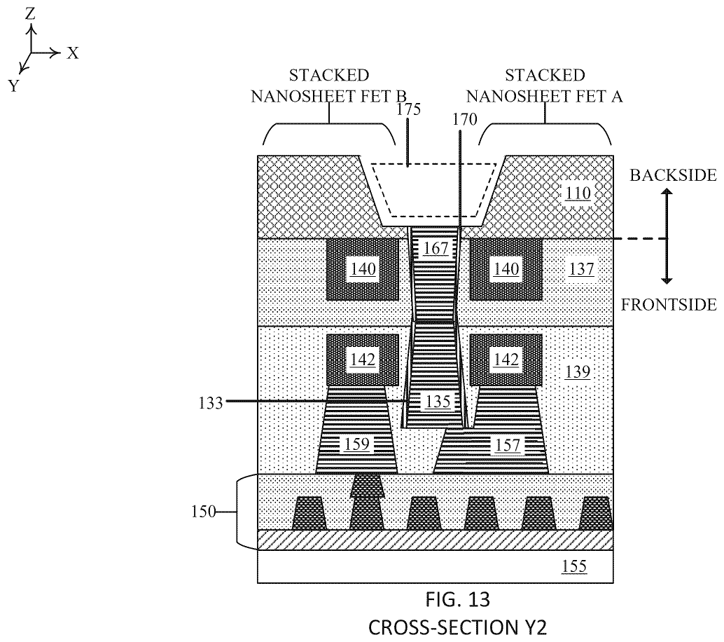

FIGS. 12 and 13 illustrate a processing stage after formation of a backside connector trench 175. A lithography layer (not shown) is formed on the shallow trench isolation layer 110, the backside interlayer dielectric layer 162, and on top of the backside contact via 166. The lithography layer (not shown) is patterned and the backside connector trench 175 is formed in the shallow trench isolation layer 110, the backside interlayer dielectric layer 162, and the backside contact via 166. The lithography layer (not shown) is removed. The backside connector trench reduces the height of the backside contact via 166, thus the backside connector trench 175 is formed on the same level as the shallow trench isolation layer 110 and the backside interlayer dielectric layer 162. The formation of the backside connector trench 175 causes the backside surface of the backside connecting via 166 to change height, such that backside surface of the backside connecting via 166 now has a fourth critical dimension CD4.

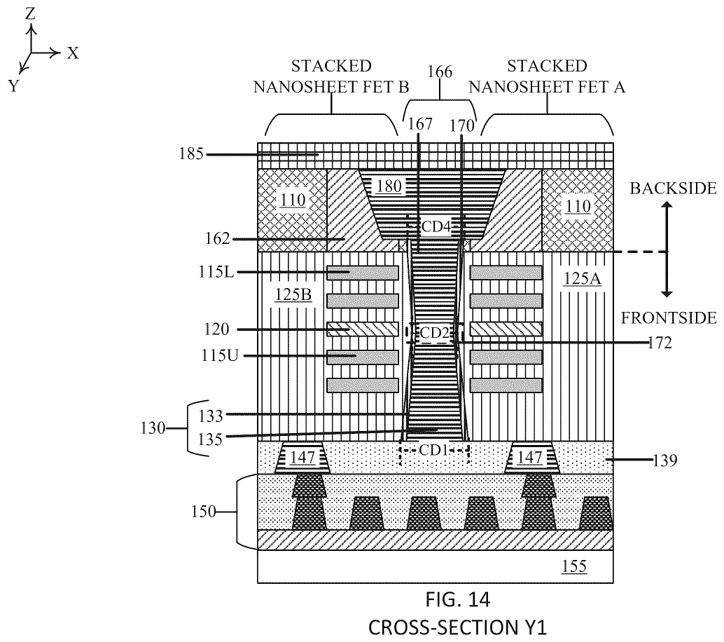

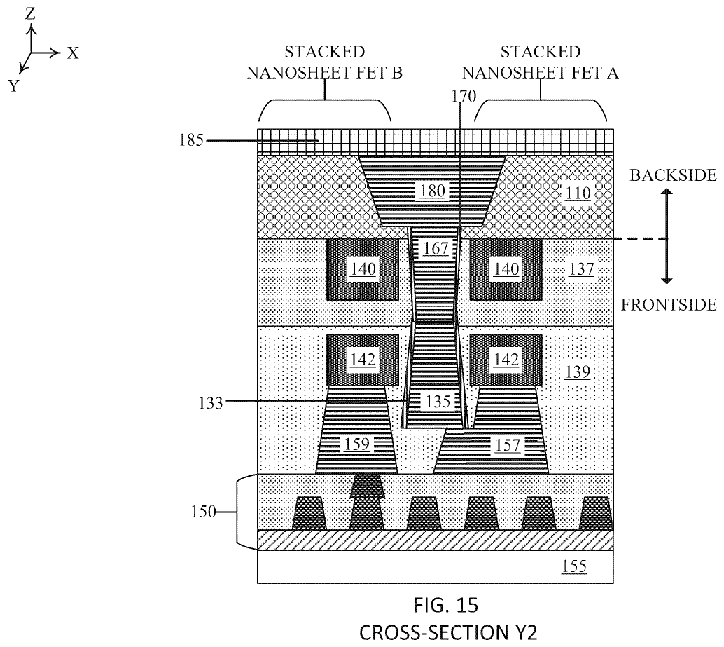

FIGS. 14 and 15 illustrate the processing stage after additional processing. The backside connector trench 175 is filled with a conductive metal, via a metallization process, to form the backside connector 180. The backside connecter 180 is located on the same level as the shallow trench isolation layer 110 and the backside interlayer dielectric layer 162. A backside interconnect 185 is formed on the backside surface of the shallow trench isolation layer 110, the backside interlayer dielectric layer 162, and the backside connector 180. The backside interconnect 185 can include one or more layers, one or more connecting vias, one or more metal lines, or other components. The backside interconnect 185 is illustrated as a single layer for illustrative purposes only.

A microelectronic structure including a first stacked FET (stacked nanosheet FET A) and a second stacked FET (stacked nanosheet FET B). The first stacked FET (stacked nanosheet FET A) is located adjacent to the second stacked FET (stacked nanosheet FET B). The first stacked FET (stacked nanosheet FET A) includes an upper source/drain 142 and a lower source/drain 140 and the first stacked FET (stacked nanosheet FET A) includes an upper and lower transistor. An upper connecting via 130 that extends from a frontside region towards a backside region to a middle region (about the height of the middle dielectric isolation layer 120). The upper connecting via 130 is located between the first stacked FET (stacked nanosheet FET A) and the second stacked FET (stacked nanosheet FET B) and the middle region is the region between the upper and lower transistor. A frontside contact 157 connected to a frontside surface of the upper source/drain 142 and a frontside surface of the upper connecting via 130. A backside connecting via 166 that extends from the backside region to the frontside region, The backside connecting via 166 intersects the upper connecting via 130 at the middle region (i.e., intersection point 172) of the first stacked FET (stacked nanosheet FET A).

The upper connecting via 130 has tapered walls, such that a width of the upper connecting via 130 narrows as it extends towards the middle region (intersection point 172). The backside connecting via 166 has tapered walls such that a width of the backside connecting via 166 narrows as it extends towards the middle region (intersection point 172). The upper connecting via 130 has a first critical dimension CD1, as measured at a frontside surface of the upper connecting via in parallel to a gate direction. The upper connecting via 130 has a second critical dimension CD2, as measured at a backside surface of the upper connecting via 130 at the intersection 172 of the upper connecting via 130 and the backside connecting via 166, where the measurement is taken in parallel to the gate direction. The first critical dimension CD1 is greater than the second critical dimension CD2. The backside connecting via 166 has a third critical dimension CD4, as measured at a backside surface of the backside connecting via in parallel to the gate direction. The third critical dimension CD4 is greater than the second critical dimension CD2.

A microelectronic structure including a first stacked FET (stacked nanosheet FET A) and a second stacked FET (stacked nanosheet FET B). The first stacked FET (stacked nanosheet FET A) is located adjacent to the second stacked FET (stacked nanosheet FET B). The first stacked FET (stacked nanosheet FET A) includes an upper source/drain 142 and a lower source/drain 140 and the first stacked FET (stacked nanosheet FET A) includes an upper and lower transistor. An upper connecting via 130 that extends from a frontside region towards a backside region to a middle region (about the height of the middle dielectric isolation layer 120). The upper connecting via 130 is located between the first stacked FET (stacked nanosheet FET A) and the second stacked FET (stacked nanosheet FET B) and the middle region is the region between the upper and lower transistor. A frontside contact 157 connected to a frontside surface of the upper source/drain 142 and a frontside surface of the upper connecting via 130. A backside connecting via 166 that extends from the backside region to the frontside region, The backside connecting via 166 intersects the upper connecting via 130 at the middle region (i.e., intersection point 172) of the first stacked FET (stacked nanosheet FET A). A shallow trench isolation layer 110 located on the backside surface of the lower source/drain 140. A connector 180 located inside the shallow trench isolation layer 110 and connected to the backside connecting via 166.

The upper connecting via 130 has tapered walls, such that a width of the upper connecting via 130 narrows as it extends towards the middle region (intersection point 172). The backside connecting via 166 has tapered walls such that a width of the backside connecting via 166 narrows as it extends towards the middle region (intersection point 172). The upper connecting via 130 has a first critical dimension CD1, as measured at a frontside surface of the upper connecting via in parallel to a gate direction. The upper connecting via 130 has a second critical dimension CD2, as measured at a backside surface of the upper connecting via 130 at the intersection 172 of the upper connecting via 130 and the backside connecting via 166, where the measurement is taken in parallel to the gate direction. The first critical dimension CD1 is greater than the second critical dimension CD2. The backside connecting via 166 has a third critical dimension CD4, as measured at a backside surface of the backside connecting via in parallel to the gate direction. The third critical dimension CD4 is greater than the second critical dimension CD2.

A backside interlayer dielectric layer 162 located on a same level as the shallow trench isolation layer 110. The connector 180 is located in the backside interlayer dielectric layer.

A method that includes the steps of forming a first stacked FET (stacked nanosheet FET A) and a second stacked FET (stacked nanosheet FET B). The first stacked FET (stacked nanosheet FET A) is located adjacent to the second stacked FET (stacked nanosheet FET B). The first stacked FET (stacked nanosheet FET A) includes an upper source/drain 142 and a lower source/drain 140 and the first stacked FET (stacked nanosheet FET A) includes an upper and lower transistor. Forming an upper connecting via 130 that extends from a frontside region towards a backside region to a middle region (about the height of the middle dielectric isolation layer 120). The upper connecting via 130 is located between the first stacked FET (stacked nanosheet FET A) and the second stacked FET (stacked nanosheet FET B) and the middle region is the region between the upper and lower transistor. Forming a frontside contact 157 connected to a frontside surface of the upper source/drain 142 and a frontside surface of the upper connecting via 130. Forming a backside connecting via 166 that extends from the backside region to the frontside region, The backside connecting via 166 intersects the upper connecting via 130 at the middle region (i.e., intersection point 172) of the first stacked FET (stacked nanosheet FET A).

The upper connecting via 130 has tapered walls, such that a width of the upper connecting via 130 narrows as it extends towards the middle region (intersection point 172).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first stacked FET and a second stacked FET, wherein the first stacked FET is located adjacent to the second stacked FET, wherein the first stacked FET includes an upper source/drain and a lower source/drain, wherein the first stacked FET includes an upper and lower transistor;
an upper connecting via that extends from a frontside region towards a backside region to a middle region, wherein the upper connecting via is located between the first stacked FET and the second stacked FET, wherein the middle region is the region between the upper and lower transistor;
a frontside contact connected to a frontside surface of the upper source/drain and a frontside surface of the upper connecting via; and
a backside connecting via that extends from the backside region to the frontside region, wherein the backside connecting via intersects the upper connecting via at the middle region of the first stacked FET.

2. The microelectronic structure of claim 1, wherein the upper connecting via has tapered walls, such that a width of the upper connecting via narrows as it extends towards the middle region.

3. The microelectronic structure of claim 2, wherein the backside connecting via has tapered walls such that a width of the backside connecting via narrows as it extends towards the middle region.

4. The microelectronic structure of claim 3, wherein the upper connecting via has a first critical dimension, as measured at a frontside surface of the upper connecting via in parallel to a gate direction.

5. The microelectronic structure of claim 4, wherein the upper connecting via has a second critical dimension, as measured at a backside surface of the upper connecting via at the intersection of the upper connecting via and the backside connecting via, wherein the measurement is taken in parallel to the gate direction.

6. The microelectronic structure of claim 5, wherein the first critical dimension is greater than the second critical dimension.

7. The microelectronic structure of claim 6, wherein the backside connecting via has a third critical dimension, as measured at a backside surface of the backside connecting via in parallel to the gate direction.

8. The microelectronic structure of claim 7, wherein the third critical dimension is greater than the second critical dimension.

9. A microelectronic structure comprising:
a first stacked FET and a second stacked FET, wherein the first stacked FET is located adjacent to the second stacked FET, wherein the first stacked FET includes an upper source/drain and a lower source/drain, wherein the first stacked FET includes an upper and lower transistor;
an upper connecting via that extends from a frontside region towards a backside region to a middle region, wherein the upper connecting via is located between the first stacked FET and the second stacked FET, wherein the middle region is the region between the upper and lower transistor;
a frontside contact connected to a frontside surface of the upper source/drain and a frontside surface of the upper connecting via;
a backside connecting via that extends from the backside region to the frontside region, wherein the backside connecting via intersects the upper connecting via at the middle region of the first stacked FET;
a shallow trench isolation layer located on the backside surface of the lower source/drain; and
a connector located inside the shallow trench isolation layer and connected to the backside connecting via.

10. The microelectronic structure of claim 9, wherein the upper connecting via has tapered walls, such that a width of the upper connecting via narrows as it extends towards the middle region.

11. The microelectronic structure of claim 10, wherein the backside connecting via has tapered walls such that a width of the backside connecting via narrows as it extends towards the middle region.

12. The microelectronic structure of claim 11, wherein the upper connecting via has a first critical dimension, as measured at a frontside surface of the upper connecting via in parallel to a gate direction.

13. The microelectronic structure of claim 12, wherein the upper connecting via has a second critical dimension, as measured at a backside surface of the upper connecting via at the intersection of the upper connecting via and the backside connecting via, wherein the measurement is taken in parallel to the gate direction.

14. The microelectronic structure of claim 13, wherein the first critical dimension is greater than the second critical dimension.

15. The microelectronic structure of claim 14, wherein the backside connecting via has a third critical dimension, as measured at a backside surface of the backside connecting via in parallel to the gate direction.

16. The microelectronic structure of claim 15, wherein the third critical dimension is greater than the second critical dimension.

17. The microelectronic structure of claim 9, further comprising:
a backside interlayer dielectric layer located on a same level as the shallow trench isolation layer.

18. The microelectronic structure of claim 17, wherein the connector is located in the backside interlayer dielectric layer.

19. A method comprising:
forming a first stacked FET and a second stacked FET, wherein the first stacked FET is located adjacent to the second stacked FET, wherein the first stacked FET includes an upper source/drain and a lower source/drain, wherein the first stacked FET includes an upper and lower transistor;
forming an upper connecting via that extends from a frontside region towards a backside region to a middle region, wherein the upper connecting via is located between the first stacked FET and the second stacked FET, wherein the middle region is the region between the upper and lower transistor;
forming a frontside contact connected to a frontside surface of the upper source/drain and connected to a frontside surface of the upper connecting via; and
forming a backside connecting via that extends from the backside region to the frontside region, wherein the backside connecting via intersects the upper connecting via at the middle region of the first stacked FET.

20. The method of claim 19, wherein the upper connecting via has tapered walls, such that a width of the upper connecting via narrows as it extends towards the middle region.
